(19) United States
(12) Patent Application Publication
(10) Pub. No.: US 2025/0140641 A1
(43) Pub. Date: May 1, 2025

(54) INTEGRATED CIRCUIT (IC) STRUCTURES WITH THERMAL COMPONENTS

(71) Applicant: Taiwan Semiconductor Manufacturing Company, Ltd., Hsinchu (TW)

(72) Inventors: Isha DATYE, Hsinchu (TW); Sam VAZIRI, San Jose, CA (US); Xinyu BAO, Fremont, CA (US)

(21) Appl. No.: 18/599,383

(22) Filed: Mar. 8, 2024

Related U.S. Application Data
(60) Provisional application No. 63/594,300, filed on Oct. 30, 2023.

(51) Int. Cl. H01L 23/373; H01L 23/00; H01L 23/522; H01L 25/065

(52) U.S. Cl. CPC H01L 23/3736; H01L 23/5226; H01L 24/29; H01L 24/32; H01L 24/83; H01L 25/0657; H01L 2224/29186; H01L 2224/32145; H01L 2224/83; H01L 2924/05032

(57) ABSTRACT

One aspect of the present disclosure pertains to an integrated circuit (IC) structure and method of fabricating thereof. The IC structure may include the first plurality of thermal vias disposed at a first pitch and the third plurality of thermal vias disposed at a second pitch, the second pitch greater than the first pitch.

### PRIORITY DATA

This application claims the benefit of U.S. Provisional Application No. 63/594,300, the entirety of which is herein incorporated.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, minimum IC feature size), thereby improving production efficiency and lowering associated costs. However, such scaling has also increased complexity of the IC manufacturing processes. Thus, realizing continued advances in IC devices and their performance requires similar advances in IC manufacturing processes and technology.

As technology nodes become smaller, ICs may be vertically stacked to form so called three-dimensional (3D) IC structures. By arranging semiconductor devices in 3 dimensions (e.g., vertically stacked die) in additional to scaling down the density of transistors in a given die, the semiconductor devices in the structure can be placed closer to each other. This can reduce wire lengths and minimize delay and resistance. Therefore, although existing IC structures having stacked ICs have been generally adequate for their intended purposes, they have not been entirely satisfactory in every aspect.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion. It is also emphasized that the figures appended illustrate only typical embodiments of this invention and are therefore not to be considered limiting in scope, for the invention may apply equally well to other embodiments. Further, the accompanying figures may implicitly describe features not explicitly described in the detailed description.

FIG. 1 illustrates perspective view of an integrated circuit (IC) structure having a plurality of stacked die having thermal vias and thermal bonding layers, according to an embodiment of the present disclosure.

FIG. 2A illustrates a cross-sectional view of an IC structure having a first exemplary configuration of die, according to an embodiment of the present disclosure.

FIG. 2B illustrates a cross-sectional view of an IC structure having the first configuration of die with another embodiment of a thermal bonding layer, according to an embodiment of the present disclosure.

FIG. 3 illustrates a cross-sectional view of an IC structure having a second exemplary configuration of die, according to an embodiment of the present disclosure.

FIG. 4 illustrates a cross-sectional view of an IC structure having a third exemplary configuration of die, according to an embodiment of the present disclosure.

FIG. 5 illustrates a cross-sectional view of an IC structure having a fourth exemplary configuration of die, according to an embodiment of the present disclosure.

FIG. 6 illustrates a cross-sectional view of an IC structure having a fifth exemplary configuration of die, according to an embodiment of the present disclosure.

FIG. 7 illustrates a cross-sectional view of an IC structure having a sixth exemplary configuration of die, according to an embodiment of the present disclosure.

FIG. 8 illustrates a cross-sectional view of an IC structure having a seventh exemplary configuration of die and another embodiment of a thermal bonding layer, according to an embodiment of the present disclosure.

FIGS. 9A and 9B illustrate a top view of a first and second IC die each having a circuit region, the circuit region having electrical vias and thermal vias, according to an embodiment of the present disclosure.

FIGS. 10A and 10B illustrate a top view of a first and second IC die each having a circuit region, the circuit region having electrical vias and thermal vias, according to an embodiment of the present disclosure.

FIGS. 11A and 11B illustrate a top view of a first and second IC die each having a circuit region, the circuit region having electrical vias and thermal vias, according to an embodiment of the present disclosure.

FIG. 12 illustrates a flow chart of a method to form a semiconductor structure, according to an embodiment of the present disclosure.

FIGS. 13A-13F illustrate the formation of an IC structure at intermediate stages of fabrication, processed in accordance with the method of FIG. 12, according to an embodiment of the present disclosure.

FIG. 14 illustrates a flow chart of a method to provide a design of a semiconductor structure, according to an embodiment of the present disclosure.

FIG. 15A illustrates a cross-sectional view of another integrated circuit (IC) structure having a plurality of stacked die having thermal vias and thermal bonding layers, according to an embodiment of the present disclosure; FIG. 15B illustrates a table of parameters for implementation in the IC structure of FIG. 15A.

FIGS. 16A, 16B, 16C illustrate embodiments of graphical representations of thermal performance of 3D-IC structure, according to aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Further, disclosed dimensions of the different features can implicitly disclose dimension ratios between the different features. Still further, the present disclosure may repeat reference numerals and/or letters in the various examples. This repetition is for the purpose of simplicity and clarity and does not in itself dictate a relationship between the various embodiments and/or configurations discussed.

The present disclosure relates to semiconductor or integrated circuit (IC) structures with provided in a stacked configuration, and particularly to incorporating thermal vias and thermal bonding layers to improve thermal or heat distribution in the structure. As 3D integration of stacked die (or chips) continues to be implemented to recognize the benefits of increased device density and scaling, it is necessary to address dissipation of heat from positions within the stacked die. For example, middle die may be limited in the thermal dissipation paths due to their location. The present disclosure describes various solutions to assist with vertical and lateral (e.g., horizontal) thermal dissipation from a hot spot in one or more die of the 3D-IC structures. In some implementations, the solutions including determining or identifying a high-power device of a die and positioning thermal vias adjacent the high-power device. In some implementations, thermal bonding layers are implemented that provide for improved thermal conductivity. The thermal vias adjacent the high-power device may provide for greater area than the thermal vias at other regions of the device. Thus, certain implementations of the present disclosure lead to improved heat dissipation in semiconductor structures such as 3D-ICs or stacked dies.

In various embodiment, the present disclosure describes an IC structure (or IC chip such as a 3D IC) including a plurality of stacked die. The die may be physically and/or electrically coupled such as by through substrate vias (TSVs). The IC structure also includes a thermal bonding layer interposing the stacked die. The IC structure also includes thermal vias to effectively dissipate heat and to reduce the hot spot temperature including near a high-power device such as in a logic region. The thermal bonding layer(s) and thermal vias and can be allow for thermal dissipation laterally and vertically and can be implemented to target hot spot regions (e.g., high-power devices) of the IC structure. The thermal bonding layer may be formed over a multi-layer interconnect (MLI) formed in a back-end of the line (BEOL) semiconductor process; and thermal vias can be formed lateral to, and in some implementations in conjunction with, the MLI in the BEOL processes. A high-power device or high-power transistor may be a transistor having a high speed and can be distinguished from other logic or memory devices such as low power logic devices (e.g., logic devices for switching functions). The high-power devices may generate hot spots, which is an area where heat is concentrated.

To that respect the following description, front-end-of-the-line (FEOL) generally refers to portions of the device (die) fabrication where functional devices such as logic and memory devices are formed. This is also referred in some instances as the device layer(s) of the structure. The FEOL features include the transistors and features thereof such as source/drain features, channel regions, gate structures. Device-level contacts or metal features extend to the terminals of the transistor. Back-end-of-the-line (BEOL) in the present disclosure generally refers to components formed after the FEOL features and include a multi-layer interconnects (MLI). The MLI provide for a plurality of metal lines (also referred to as interconnect lines) and interposing vias that provide electrical connections including to the FEOL features. The metal lines provide for horizontal routing and the vias provide for a vertical routing to connect metal lines at different metal layers. Any number of metal layers may be used including for example, exemplary MLI may include five (5) or more metal lines vertically stacked typically referred to as M1, M2, M3, and so forth. The MLI includes dielectric or insulating materials that surround the metal lines and vias to provide for suitable direction of the signals carried in the lines, the dielectric can be referred to as an inter-metal dielectric (IMD) as discussed below.

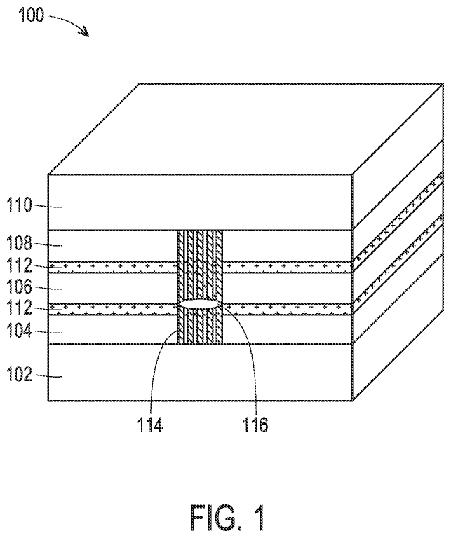

FIG. 1 illustrates a perspective view of a semiconductor or IC structure 100 including a substrate 102, a plurality of stacked die 104, 106, and 108, and an overlying heatsink 110. The IC structure 100 may be referred to as a 3D-IC. While three die are illustrated, any number of die may be possible. The first die 104, second die 106, and third die 108 may include logic devices including high-power devices such as high-power logic devices, memory devices, and/or other functionality. The first die 104, second die 106, and third die 108 may be the same as one another, or the first die 104, second die 106, and third die 108 may be different in functionality and/or footprint.

The IC structure 100 may be an IC package mounted onto a printed circuit board (PCB). In other embodiments, the substrate 102 may include a PCB, a semiconductor substrate, an interposer, a dielectric substrate and/or other supportive feature. In some implementations, the substrate 102 may include conductive traces connecting to the overlying die such as die 104. In some implementations, the substrate 102 may include input/output terminals such as bumps, balls, or pillars (not shown).

The first die 104 is connected or attached to the second die 106 by a thermal bonding layer 112. The second die 106 is connected or attached to the third die 108 by a thermal bonding layer 112. In some implementations, a thermal bonding layer 112 may also interpose the die 108 and heatsink 110 (not shown). The thermal bonding layers 112 may be different in composition and thickness than one another, or in other embodiments, may be substantially the same. The thermal bonding layer 112 may include on or more materials providing a thermal conductivity (k) that ranges between approximately 10 to 500 Watts per meter Kelvin (W/m-K). In an embodiment, a thickness of the thermal bonding layer 112 is between approximately 1 μm to approximately 50 μm. Exemplary materials for the thermal bonding layer 112 include boron nitride (BN), beryllium oxide (BeO), diamond, aluminum nitride (AlN), aluminum oxide (Al₂O₃).

In an embodiment, the thermal bonding layer 112 includes AlN. In a further embodiment, the thermal bonding layer has a thermal conductivity (k) of between approximately 20 and 200 W/m-K. In a further embodiment, the thermal bonding layer has a thermal conductivity (k) approximately 30 W/m-K. In an embodiment, the thermal bonding layer 112 includes diamond. In a further embodiment, the thermal bonding layer has a thermal conductivity (k) between approximately 200 and 500 W/m-K. In an embodiment, the thermal bonding layer 112 includes boron nitride (BN). In a further embodiment, the thermal bonding layer has a thermal conductivity k (in-plane) between approximately 50 and 200 W/m-K and/or thermal conductivity k (cross-plane) between approximately 2 and 10 W/m-K. In an embodiment, the thermal bonding layer 112 includes Al₂O₃. In a further embodiment, the thermal bonding layer has a thermal conductivity (k) between approximately 10 and 30 W/m-K. In an embodiment, the thermal bonding layer 112 includes BeO. In a further embodiment, the thermal bonding layer has a thermal conductivity (k) between approximately 200 and 500 W/m-K.

A plurality of thermal vias 114 extend through one or more of the first die 104, the second die 106 and the third die 108. The thermal vias 114 may be provided at a localized region. In other words, in some implementations, the thermal vias are not located throughout each of the die 104, 106, 108 but are provided in a defined regions thereof. In the present embodiment, the thermal vias 114 are positioned adjacent a hot spot 116 of the structure 100. In some embodiments, other regions of any of die 104, 106, or 108 may include no thermal vias, include few thermal views, or include a smaller area of thermal vias (e.g., percentage area of thermal via versus non-thermal via, which can be measured for example from a top view). The hot spot 116 may be a region of raised thermal conditions (e.g., heat) such as generated by high power semiconductor devices (e.g., high power transistors). In some implementations, the top spot is an area (e.g., 100-300 micron square area with a higher thermal (W/cm2) energy). While the thermal vias 114 are illustrated as extending through each die, the thermal vias 114 may be positioned in the BEOL features of each die including as discussed below. Exemplary materials for the thermal vias includes copper (Cu), diamond nanoparticles, AlN, boron nitride nanoparticles, and/or other suitable thermal-conducting materials.

The thermal vias 114 may be electrically isolated from the electrically conductive via and metal lines of the structure 100. In other words, the thermal vias 114 may be floating. The electrically conductive elements may be those metallization coupled to semiconductor devices (e.g., transistors) of a die. In an embodiment, the thermal vias 114 are spaced a distance of approximately 50 nanometers (nm) to approximately 500 nm from the electrical components (e.g., electrical via) (e.g., as measured in an x-direction/laterally). In an embodiment, the thermal vias 114 may be approximately 100 nm to approximately 10 μm in width. (In some implementations, the electrical components (e.g., electrical vias) are few nanometers to a few microns (μm).) The thermal vias 114 have direct contact to the thermal bonding layer 112.

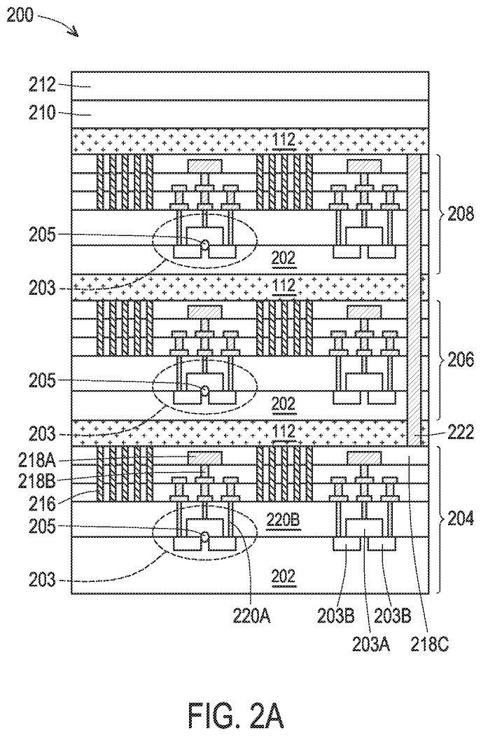

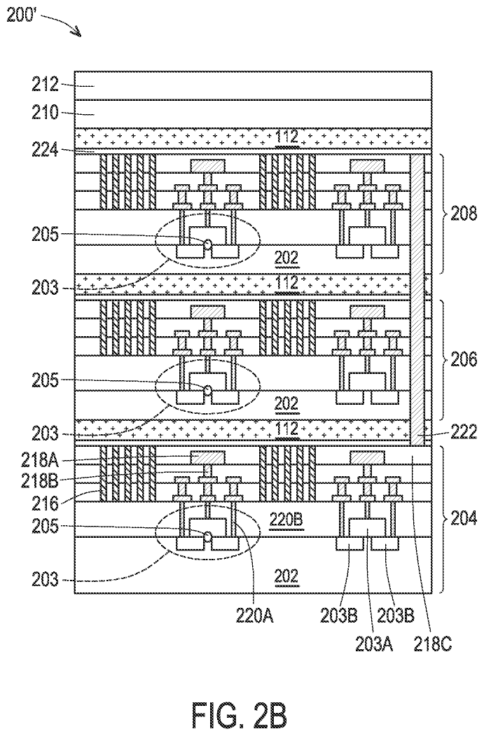

FIGS. 2A-8 illustrate cross-sectional views of 3D-ICs that maybe implementations of the structure 100 of FIG. 1. FIG. 2A illustrates a semiconductor structure (e.g., 3D-IC) 200 having a first die 204, a second die 206, a third die 208, and an overlying substrate 210 and component (e.g., heat sink) 212. One or more features may be omitted from structure 200, and/or other features may be added. As stated above, the semiconductor structure 200 may be an embodiment of the semiconductor structure 100 of FIG. 1 and the description provided above applies to the structure 200. In an embodiment, the first die 204 is a logic device, the second die 206 is a logic device, and the third die 208 is a logic device. Exemplary logic devices include central processing unit (CPU), graphic processing unit (GPU), various processors, various controllers, and/or other chips were an operation is performed or set of instructions is executed. A memory die or chip is a die that stores and retrieves data.

Each die 204, 206, and 208 includes a semiconductor substrate 202 and a plurality of semiconductor devices 203 formed on the semiconductor substrate in FEOL processes. Such FEOL processes may form semiconductor devices 203 such as transistors on the substrate 202 to serve different functions. For example, as discussed above with respect to a logic die, these various transistors may form a central processing unit (CPU), a graphics process unit (GPU), access transistors for memory devices, image signal processing (ISP) circuitry, and/or other suitable circuitry. The transistors may be planar transistors or multi-gate transistors. A planar device refers to a device having a gate structure that engages a planar surface of a semiconductor active region. A multi-gate device generally refers to a device having a gate structure, or portion thereof, disposed over more than one side of a channel region. Fin-like field effect transistors (FinFETs) and gate-all-around (GAA) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). A GAA transistor has a gate structure that can extend, partially or fully, around a channel region to provide access to the channel region on two or more sides. Because its gate structure surrounds the channel regions, a GAA transistor may also be referred to as a surrounding gate transistor (SGT) or a multi-bridge-channel (MBC) transistor. The channel region of a GAA transistor may be formed from nanowires, nanosheets, or other nanostructures and for that reasons, a GAA transistor may also be referred to as a nanowire transistor or a nanosheet transistor. The transistors are referred to herein generally, and each of the configurations discussed applies to the embodiments herein. As illustrated, the semiconductor device 203 includes a gate structure 203A and two source/drain regions 203B.

In some embodiments, the semiconductor substrate 202 includes silicon (Si). Alternatively or additionally, substrate 202 includes another elementary semiconductor, such as germanium (Ge); a compound semiconductor, such as silicon carbide, gallium arsenide, gallium phosphide, indium phosphide, indium arsenide, and/or indium antimonide; an alloy semiconductor, such as silicon germanium (SiGe), GaAsP, AlInAs, AlGaAs, GaInAs, GaInP, and/or GaInAsP; or combinations thereof. In some implementations, the substrate 202 includes one or more group III-V materials, one or more group II-IV materials, or combinations thereof. In some implementations, the substrate 202 is a semiconductor-on-insulator substrate, such as a silicon-on-insulator (SOI) substrate, a silicon germanium-on-insulator (SGOI) substrate, or a germanium-on-insulator (GeOI) substrate. Semiconductor-on-insulator substrates can be fabricated using separation by implantation of oxygen (SIMOX), wafer bonding, and/or other suitable methods.

As indicated above, the semiconductor device 203 may include a transistor having source/drain regions 203B and a gate structure 203A in various configurations. The source/drain regions 203B may be doped regions and/or epitaxially grown regions defining the source/drain feature associated with a gate structure 203A of the semiconductor device. The source/drain regions 203B may be deposited using vapor-phase epitaxy (VPE), ultra-high vacuum CVD (UHV-CVD), molecular beam epitaxy (MBE), and/or other suitable processes. When source/drain region 203B is n-type, it may include silicon (Si) doped with an n-type dopant, such as phosphorus (P) or arsenic (As). When a source/drain region 306 is p-type, it may include silicon germanium (SiGe) doped with a p-type dopant, such as boron (B) or boron difluoride (BF₂). In some embodiments, the source/drain regions 203B may include multiple layers such as layers with different dopant concentrations.

The gate structure 203A may include an interfacial layer, a gate dielectric layer, and a gate electrode. The interfacial layer of the gate structures 203A may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The gate dielectric layer may be formed on the interfacial layer. The gate dielectric layer may include a high-k dielectric material, such as hafnium oxide. Alternatively, the gate dielectric layer of the gate structures 203A may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr) TiO₃ (BST), silicon nitride (SiN), silicon oxynitride (SiON), combinations thereof, or other suitable material. The gate dielectric layer may be formed by ALD, physical vapor deposition (PVD), CVD, oxidation, and/or other suitable methods. The gate electrode layer of the gate structures 203A may include a single layer or alternatively a multi-layer structure, such as various combinations of a metal layer with a selected work function to enhance the device performance (work function metal layer), a liner layer, a wetting layer, an adhesion layer, a metal alloy, or a metal silicide. By way of example, the gate electrode layer may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAIC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof.

Device level contacts 220A are formed connected to the semiconductor device 203 terminals and extend through an inter-layer dielectric (ILD) 220B. The ILD layer 220B may be deposited using PECVD, FCVD, spin-on coating, or other suitable deposition technique. In some embodiments, after formation of the ILD layer 220B, the structure may be annealed to improve integrity of the ILD layer 220B. Although not explicitly shown in figures it is understood a contact etch stop layer (CESL) may be deposited before the ILD layer 220B is deposited such that the CESL is disposed between the ILD layer 220B and the transistor features. The CESL may include silicon nitride or silicon oxynitride and may be deposited using CVD, ALD, or a suitable method. Contact structures 220A extend through the ILD layer 220B to the source/drain regions 203B and the gate structure 203A and provide an electrical connection to the semiconductor device 203. The contact structures 220A may be referred to as middle-end-of-the-line (MEOL) structures. The contact structures 220A may include ruthenium (Ru), cobalt (Co), nickel (Ni), tungsten (W), copper (Cu), or other metals, as examples. In some embodiments, the contact structures 220A may include a barrier layer to interface the ILD layer 220B. Such a barrier layer may include a metal nitride, such as titanium nitride, tantalum nitride, tungsten nitride, cobalt nitride, or nickel nitride. Additionally, in order to reduce contact resistance, a silicide feature may be a portion of the contact structure 220A and interface the transistor feature with which it contacts, such as gate structure 203A. The contact structure 220A may be formed by photolithography to pattern the ILD layer 220B, etching contact holes in the ILD layer 220B, and depositing conductive material using CVD, PVD, or other suitable method. Again, the device level contacts 220A carry an electrical signal of the semiconductor device 203 to provide the functionality of the respective die.

A multi-layer interconnect (MLI) is formed over the substrate 202 and includes a plurality of metal lines 218A and interposing metal vias 218B providing electrical connection to the semiconductor device 203 (through the device level contacts 220A). The metal lines 218A and metal vias 218B may also be referred to as electrical lines and electrical vias as they function to carry a single of the device. IMD layers 218C provide insulating layers within and around the MLI. The MLI is a BEOL feature as discussed above. While only three metallization layers are shown for ease of illustration, the MLI of the semiconductor structure 200 may include any plurality layers in the MLI, for example, an MLI may typically include about five (5) to about twenty (20) metal layers (or metallization layers including a metal line 218A). Each of the metal layers of the MLI include multiple vias 218B and metal lines 218A embedded in a dielectric or insulating layer, which may also be referred to herein as an intermetal dielectric (IMD) layer 218C. The vias 218B and metal lines 218A may be formed of titanium (Ti), ruthenium (Ru), nickel (Ni), cobalt (Co), copper (Cu), molybdenum (Mo), tungsten (W), aluminum (Al), and/or other suitable materials. In an embodiment, they are formed of copper (Cu). The IMD layer 218C may include silicon oxide, tetraethylorthosilicate (TEOS) oxide, un-doped silicate glass (USG), or doped silicate glass such as borophosphosilicate glass (BPSG), fused silicate glass (FSG), phosphosilicate glass (PSG), boron doped silicate glass (BSG), and/or other suitable dielectric materials. In one embodiment, the IMD layer 218C includes silicon oxide.

Thermal vias 216 are formed laterally adjacent to the electrical lines and vias of the MLI and the thermal vias 216 also extend through the IMD layers 218C. Thermal vias 216 may be substantially similar to thermal vias 114 discussed with reference to FIG. 1. The thermal vias 216 may vertically span an entire height of the MLI feature. In a further embodiment, the thermal vias 216 may be positioned above a second metal layer (M2) of the MLI. In such an embodiment, a terminal end of the thermal vias 216 may interface the IMD 218C. In some implementations, one end is interfacing the ILD 220B and the opposite end directly contacts a surface of the thermal bonding layer 112. The thermal vias 216 do not electrically connect to any of the semiconductor devices 203 (e.g., transistor devices). Instead, they act as heat absorbing features embedded in the IMD layers 218C. Exemplary materials for the thermal via 216 includes copper (Cu), diamond nanoparticles, AlN, boron nitride nanoparticles, and/or other suitable materials.

The thermal vias 216 may be placed adjacent those semiconductor devices 203 generating a hot spot 205, which may be a region of raised thermal conditions (e.g., heat) such as generated by high power semiconductor devices (e.g., high power transistors). In other regions of the die (204, 206, or 208) without a generated hot spot, there may be fewer to no thermal vias 216. In some implementations, a lateral distance between the electrical metal lines 218A or vias 218B and the thermal vias 216 is between approximately 50 nm and approximately 500 nm.

As illustrated a substrate 210 is formed over a top die, here die 208. In an embodiment, the substrate 210 is a carrier substrate. The substrate 210 may include silicon (Si), or other semiconductor materials such as germanium (Ge), silicon carbide (SiC), silicon germanium (SiGe), diamond, and/or other suitable substrate. In some implementations the substrate 210 may be omitted, and/or be used for fabrication to provide structural support. A heat sink 212 may be formed at an upper portion of the structure 200 (e.g., interfacing the thermal bonding layer 112).

Thermal bonding layers 112 are disposed between each die (e.g., between die 204 and die 206, between die 206 and die 208) and between an upper die and overlying component (e.g., between die 208 and substrate 210). The thermal bonding layers 112 may be substantially similar to the thermal bonding layers 112, discussed above with reference to FIG. 1. In an embodiment, the thermal bonding layers 112 are a single layer. For example, in a further embodiment, the thermal bonding layers 112 are a single layer of AlN. Thus, in some implementations, a composition of the thermal bonding layer 112 interfaces a backside of the substrate 202 of an upper die (e.g., die 206) and an upper surface of a lower die (e.g., die 204) such as an uppermost dielectric material of the MLI structure (e.g., IMD 218C). The thickness of the thermal bonding layer 112 may vary between 0.1 μm to 50 μm. In an embodiment, the thickness of the thermal bonding layer 112 may be approximately 10 μm. The thermal bonding layer 112 may be deposited by physical vapor deposition (PVD), chemical vapor deposition (CVD), and/or other suitable process. In some implementations, the deposition is performed at a temperature of less than approximately 400° C. (As discussed in FIG. 2B, a think bonding layer (e.g., nitride or oxide) may be deposited below the thermal bonding layer 112).

A through substrate via (TSV) 222 extends through one or more devices, e.g., die 206 and die 208. The TSV 222 may provide electrical connection between the dies. The TSV 222 may include titanium (Ti), ruthenium (Ru), nickel (Ni), cobalt (Co), copper (Cu), molybdenum (Mo), tungsten (W), aluminum (Al), and/or suitable materials. In some implementations, the TSV 222 is connected to one or more MLI structures of the die 204, 206, or 208. In some implementations, the TSV 222 provides an input/output path for access to upper die in the 3D-IC 200.

Still referring to the structure 200, various input/output features may be included (not shown) such as a controlled collapse chip connection (C4) layer, a package substrate, an interposer substrate, a ball-grid array (BGA) structure, a printed circuit board (PCB) and/or other features. Further, each of the die 204, 206, 208 may have a different size (footprint) and/or functionality.

FIG. 2B illustrates a cross-sectional view of an IC structure 200′, according to an embodiment of the present disclosure. The IC structure 200′ in FIG. 2B is similar to the IC structure of FIG. 2A, and the similar features will not be described again for the sake of brevity. The difference is that there is a bonding layer 224 below the thermal bonding layer 112. In an embodiment, the bonding layer 224 may be an oxide material or nitride material. In some implementations, the bonding layer 224 may include Al₂O₃, SiO₂, SiN, and/or other suitable materials. In a further implementation, the thermal bonding layer 112 is AlN and is disposed directly on the bonding layer 224. Like the IC structure of FIG. 2A, the IC structure 200′ of FIG. 2B is also an embodiment of the structure 100 of FIG. 1, the description of which equally applies here. The bonding layer 224 is thinner than the thermal bonding layer 112. The thickness of the thermal bonding layer 112 may vary between 0.1 μm to 50 μm; the thickness of the bonding layer 224 may be between 10 and 70 percent of the thermal bonding layer 112. In some implementations, the thicknesses and/or materials of the bonding layer and the thermal bonding layer may be determined by considering the desired effective thermal conductivity (e.g., thermal conductivity (k) of the resultant stack of layers).

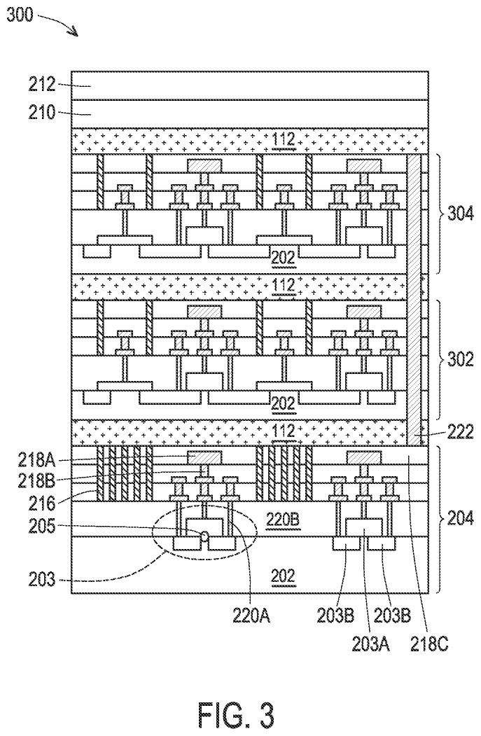

FIG. 3 illustrates a cross-sectional view of an IC structure 300, according to an embodiment of the present disclosure. The IC structure 300 in FIG. 3 is similar to the IC structure 200 in FIG. 2A, and the similar features will not be described again for the sake of brevity. Similar to as discussed above, the IC structure 300, which may also be referred to as a 3D-IC, is an embodiment of the structure 100 of FIG. 1, the description of which applies here as well. FIG. 3 includes a first die 204, a second die 302, and a third die 304. The first die 204 may be a logic die. The first die 204 may include a high-power device 203 having a hot spot 205. A plurality of thermal vias 216 are disposed adjacent the high-power device 203. The second die 302 may be a memory die and may include semiconductor devices 203 to effectuate the memory functions. In some implementations, the semiconductor devices 203 do not exhibit a hot spot. In some embodiments, a second plurality of thermal vias 216 are disposed on the second die 302. In an embodiment, quantity of the second plurality of thermal vias 216 are less than the quantity of the first plurality of thermal vias 216 (e.g., for a given area, such as a vertically aligned area). In an embodiment, an area of the second plurality of thermal vias 216 is less than an area of the first plurality of thermal vias 216 (e.g., when considered from a top view or cross-sectional view). The third die 304 may also be a memory die. The third die 304 may include semiconductor devices 203 designed to effectuate the memory die's purpose. And in some implementations, the semiconductor devices 203 of the third die 304 also do not have a hot spot. A third plurality of thermal vias 216 are disposed on the third die 304. In an embodiment, the quantity of the third plurality of thermal vias 216 is less than the quantity of the first plurality of thermal vias 216 of the die 204 (e.g., for a given area of the respective die). In an embodiment, an area of the third plurality of thermal vias 216 is less than an area of the first plurality of thermal vias 216 (e.g., when considered from a top view or cross-sectional view). As illustrated, a single thermal bonding layer 112 is disposed between die 204 and die 302 and a single thermal bonding layer 112 is disposed between die 302 and the die 304. In an embodiment, a single thermal bonding layer 112 is disposed between the die 304 and the substrate 210. In an example, a single thermal bonding layer 112 is AlN. In other implementations, one or more bonding layer 112 is a multilayer structure such as the multi-layer structure of thermal bonding layer 112 and bonding layer 224 illustrated in FIG. 2B.

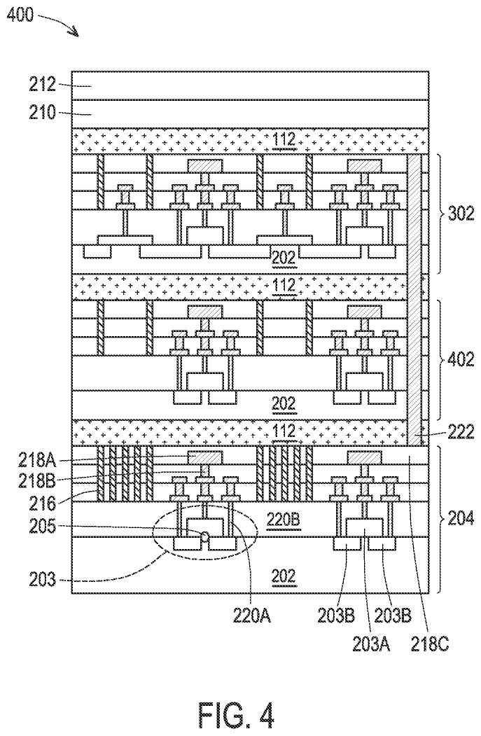

FIG. 4 illustrates a cross-sectional view of an IC structure 400, according to an embodiment of the present disclosure. The IC structure 400 in FIG. 4 is similar to the IC structure 200 in FIG. 2A, and the similar features will not be described again for the sake of brevity. Similar to as discussed above, the IC structure 400, which may also be referred to as a 3D-IC, is an embodiment of the structure 100 of FIG. 1, the description of which applies here as well. FIG. 4 includes a first die 204, a second die 402, and a third die 302. The first die 204 may be a logic die. The first die 204 may include a high-power device 203 having a hot spot 205. A first plurality of thermal vias 216 are disposed adjacent the high-power device 203. The second die 402 may be a logic die. The second die 402 may include semiconductor devices 203 to effectuate logic functions. In some implementations, the semiconductor devices 203 of the second die 402 do not exhibit a hot spot. In an embodiment, the second die 402 is a logic die comprising low-power devices (e.g., low-power transistor devices 203). In some embodiments, a second plurality of thermal vias 216 are disposed on the second die 402. In an embodiment, quantity of the second plurality of thermal vias 216 are less than the quantity of the first plurality of thermal vias 216 of the first die 204 (e.g., for a given area, such as a vertically aligned area). In an embodiment, an area of the second plurality of thermal vias 216 is less than an area of the first plurality of thermal vias 216 of the first die 204 (e.g., when considered from a top view or cross-sectional view). The third die 302 may be a memory die. The third die 302 may include semiconductor devices 203 to effectuate memory functions. In some implementations, the semiconductor devices 203 of the third die 302 do not have a hot spot. In some embodiments, a third plurality of thermal vias 216 are disposed on the third die 302. In an embodiment, quantity of the third plurality of thermal vias 216 of the third die 302 are less than the quantity of the first plurality of thermal vias 216 of the first die 204 (e.g., for a given area, such as a vertically aligned area). In an embodiment, an area of the third plurality of thermal vias 216 of the third die 302 is less than an area of the first plurality of thermal vias 216 of the first die 204 (e.g., when considered from a top view or cross-sectional view). As illustrated, a single thermal bonding layer 112 is disposed between die 204 and die 402 and a single thermal bonding layer 112 is disposed between die 402 and the die 302. In an embodiment, a single thermal bonding layer 112 is disposed between the die 302 and the substrate 210. For example, a single thermal bonding layer 112 may include a thermally conductive material of AlN. In other implementations, one or more bonding layer 112 is a multilayer structure such as the multi-layer structure of thermal bonding layer 112 and bonding layer 224 illustrated in FIG. 2B.

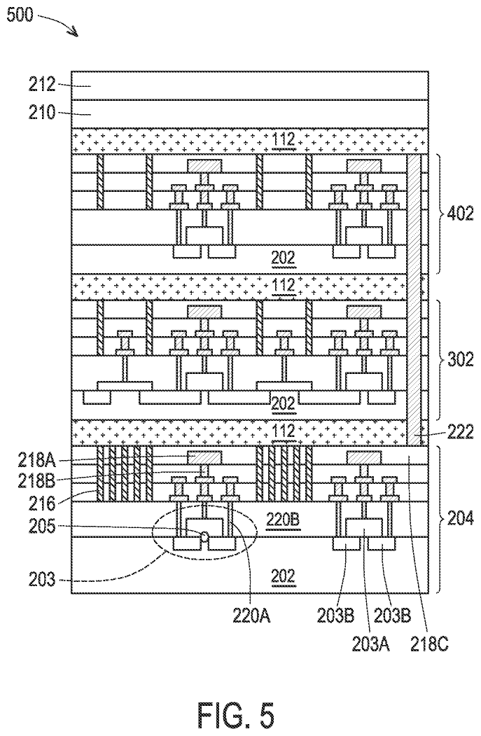

FIG. 5 illustrates a cross-sectional view of an IC structure 500, according to an embodiment of the present disclosure. The IC structure 500 in FIG. 5 is similar to the IC structure 200 in FIG. 2A, and the similar features will not be described again for the sake of brevity. Similar to as discussed above, the IC structure 500, which may also be referred to as a 3D-IC, is an embodiment of the structure 100 of FIG. 1, the description of which applies here as well. FIG. 5 includes a first die 204, a second die 302, and a third die 402. The first die 204 may be a logic die. The first die 204 may include a high-power device 203 having a hot spot 205. A first plurality of thermal vias 216 are disposed adjacent the high-power device 203. The second die 302 may be a memory die. The second die 302 may include semiconductor devices 203 to effectuate a memory function. In some implementations, the semiconductor devices 203 of the second die 302 do not have a hot spot. In some embodiments, a second plurality of thermal vias 216 are disposed on the second die 302. In an embodiment, quantity of the second plurality of thermal vias 216 of the second die 302 are less than the quantity of the first plurality of thermal vias 216 of the first die 204 (e.g., for a given area, such as a vertically aligned area). In an embodiment, an area of the second plurality of thermal vias 216 of the die 302 is less than an area of the first plurality of thermal vias 216 of the first die 204 (e.g., when considered from a top view or cross-sectional view). The third die 402 may be a logic die. The third die 402 may include semiconductor devices 203 to effectuate logic functions. In some implementations, the semiconductor devices 203 of the third die 402 do not have a hot spot. In an embodiment, the third die 402 is a logic die of low-power devices (e.g., low-power transistor devices 203). In some embodiments, a third plurality of thermal vias 216 are disposed on the third die 402. In an embodiment, quantity of the third plurality of thermal vias 216 of the third die 402 are less than the quantity of the first plurality of thermal vias 216 of the first die 204 (e.g., for a given area, such as a vertically aligned area). In an embodiment, an area of the third plurality of thermal vias 216 of the third die 402 is less than an area of the first plurality of thermal vias 216 of the first die 204 (e.g., when considered from a top view or cross-sectional view). As illustrated, a single thermal bonding layer 112 is disposed between die 204 and die 302 and a single thermal bonding layer 112 is disposed between die 302 and the die 402. In an embodiment, a single thermal bonding layer 112 is disposed between the die 402 and the substrate 210. For example, a single thermal bonding layer 112 is AlN. In other implementations, one or more bonding layer 112 is a multilayer structure such as the multi-layer structure of thermal bonding layer 112 and bonding layer 224 illustrated in FIG. 2B.

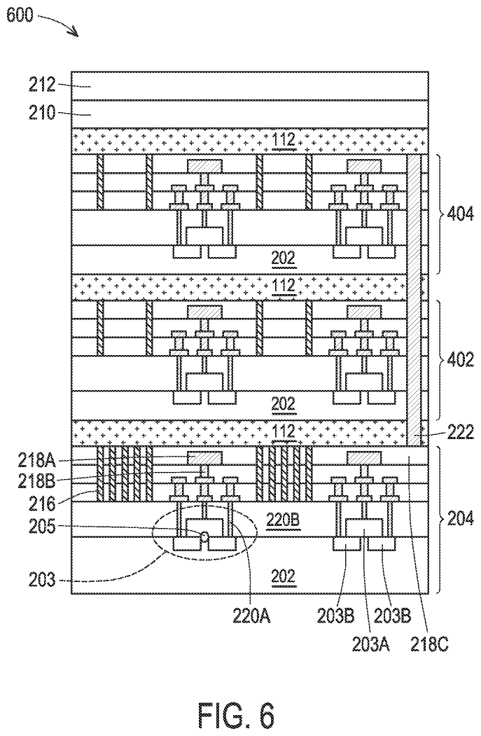

FIG. 6 illustrates a cross-sectional view of an IC structure 600, according to an embodiment of the present disclosure. The IC structure 600 in FIG. 6 is similar to the IC structure 200 in FIG. 2A, and the similar features will not be described again for the sake of brevity. Similar to as discussed above, the IC structure 600, which may also be referred to as a 3D-IC, is an embodiment of the structure 100 of FIG. 1, the description of which applies here as well. FIG. 6 includes a first die 204, a second die 402, and a third die 404. The first die 204 may be a logic die. The first die 204 may include a high-power device 203 having a hot spot 205. A first plurality of thermal vias 216 are disposed adjacent the high-power device 203. The second die 402 may be a logic die. The second die 402 may include semiconductor devices 203 to effectuate logic functions. In some implementations, the semiconductor devices 203 of the second die 402 do not have a hot spot. In an embodiment, the second die 402 is a logic die of low-power devices (e.g., low-power transistor devices 203). In some embodiments, a second plurality of thermal vias 216 are disposed on the second die 402. In an embodiment, quantity of the second plurality of thermal vias 216 of the second die 402 are less than the quantity of the first plurality of thermal vias 216 of the first die 204 (e.g., for a given area, such as a vertically aligned area). In an embodiment, an area of the second plurality of thermal vias 216 of the die 402 is less than an area of the first plurality of thermal vias 216 of the first die 204 (e.g., when considered from a top view or cross-sectional view). The third die 404 may be a logic die. The third die 404 may include semiconductor devices 203 to effectuate the logic functions. In some implementations, the semiconductor devices 203 of the second die 402 do not have a hot spot. In an embodiment, the third die 404 is a logic die of low-power devices (e.g., low-power transistor devices 203). In some embodiments, a third plurality of thermal vias 216 are disposed on the third die 404. In an embodiment, quantity of the third plurality of thermal vias 216 of the third die 404 are less than the quantity of the first plurality of thermal vias 216 of the first die 204 (e.g., for a given area, such as a vertically aligned area). In an embodiment, an area of the third plurality of thermal vias 216 of the die 404 is less than an area of the first plurality of thermal vias 216 of the first die 204 (e.g., when considered from a top view or cross-sectional view). As illustrated, a single thermal bonding layer 112 is disposed between die 204 and die 402 and a single thermal bonding layer 112 is disposed between die 402 and the die 404. In an embodiment, a single thermal bonding layer 112 is disposed between the die 404 and the substrate 210. For example, a single thermal bonding layer 112 is AlN. In other implementations, one or more bonding layer 112 is a multilayer structure such as the multi-layer structure of thermal bonding layer 112 and bonding layer 224 illustrated in FIG. 2B.

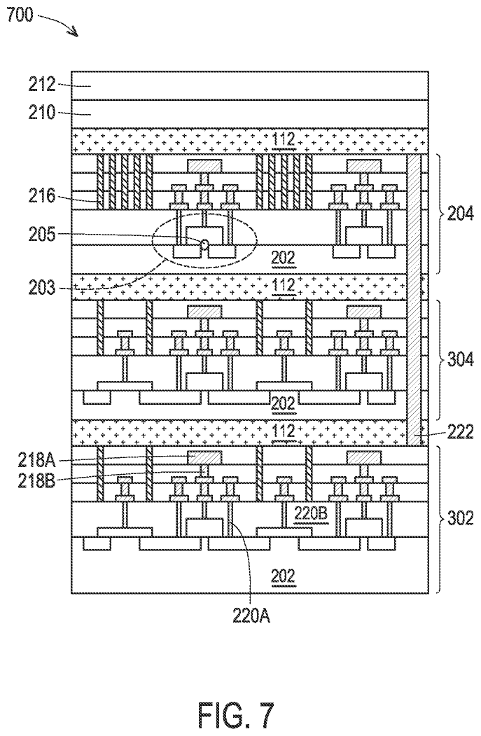

FIG. 7 illustrates a cross-sectional view of an IC structure 700, according to an embodiment of the present disclosure. The IC structure 700 in FIG. 7 is similar to the IC structure 200 in FIG. 2A, and the similar features will not be described again for the sake of brevity. Similar to as discussed above, the IC structure 700, which may also be referred to as a 3D-IC, is an embodiment of the structure 100 of FIG. 1, the description of which applies here as well. FIG. 7 includes a first die 302, a second die 304, and a third die 204. The third die 204 may be a logic die. The third die 204 may include a high-power device 203 having a hot spot 205. A third plurality of thermal vias 216 are disposed adjacent the high-power device 203. The second die 304 may be a memory die. The second die 304 may include semiconductor devices 203 to effectuate memory functions. In some implementations, the semiconductor devices 203 of the second die 304 do not have a hot spot. In some embodiments, a second plurality of thermal vias 216 are disposed on the second die 304. In an embodiment, quantity of the second plurality of thermal vias 216 of the second die 304 are less than the quantity of the third plurality of thermal vias 216 of the third die 204 (e.g., for a given area, such as a vertically aligned area). In an embodiment, an area of the second plurality of thermal vias 216 of the die 304 is less than an area of the third plurality of thermal vias 216 of the third die 204 (e.g., when considered from a top view or cross-sectional view). The first die 302 may be a memory die. The first die 302 may include semiconductor devices 203 to effectuate the memory functions. In some implementations, the semiconductor devices 203 of the first die 302 do not have a hot spot. In some embodiments, a first plurality of thermal vias 216 are disposed on the first die 302. In an embodiment, quantity of the first plurality of thermal vias 216 of the first die 302 are less than the quantity of the third plurality of thermal vias 216 of the third die 204 (e.g., for a given area, such as a vertically aligned area). In an embodiment, an area of the first plurality of thermal vias 216 of the die 302 is less than an area of the third plurality of thermal vias 216 of the third die 204 (e.g., when considered from a top view or cross-sectional view). As illustrated, a single thermal bonding layer 112 is disposed between die 302 and die 304 and a single thermal bonding layer 112 is disposed between die 304 and the die 204. In an embodiment, a single thermal bonding layer 112 is disposed between the die 204 and the substrate 210. For example, a single thermal bonding layer 112 is AlN. In other implementations, one or more bonding layer 112 is a multilayer structure such as the multi-layer structure of thermal bonding layer 112 and bonding layer 224 illustrated in FIG. 2B. For example, in some implementations between the memory die 302 and the memory die 304, a multi-layer structure of a thermal bonding layer 112 and a bonding layer 224 are provided.

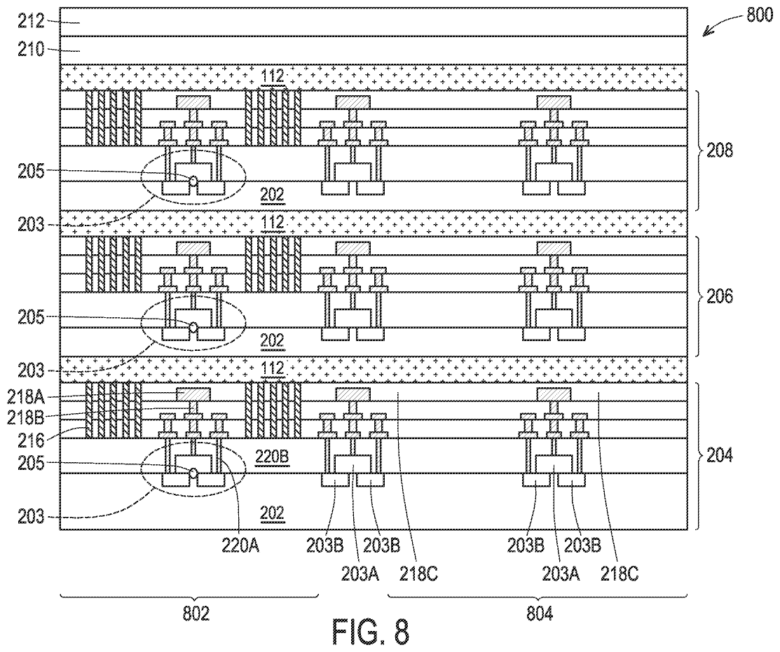

FIG. 8 illustrates a cross-sectional view of an IC structure 800, according to an embodiment of the present disclosure. The IC structure 800 in FIG. 8 is similar to the IC structure of FIG. 2A, and the similar features will not be described again for the sake of brevity. The difference is that the structure 800 illustrates a first region 802A of the structure 800 and a second region 804 of the structure 800. The first region 802A includes a plurality of thermal vias 216, which may be the same or different between die of the 3D-IC structure that is the IC structure 800. The second region 802B does not include thermal vias 216. In other words, the thermal vias 216 are localized to an area of a die and/or dies adjacent to or vertically aligned with a transistor that generates a hot spot. Like the IC structure of FIG. 2A, the IC structure 800 of FIG. 8 is also an embodiment of the structure 100 of FIG. 1, the description of which equally applies here.

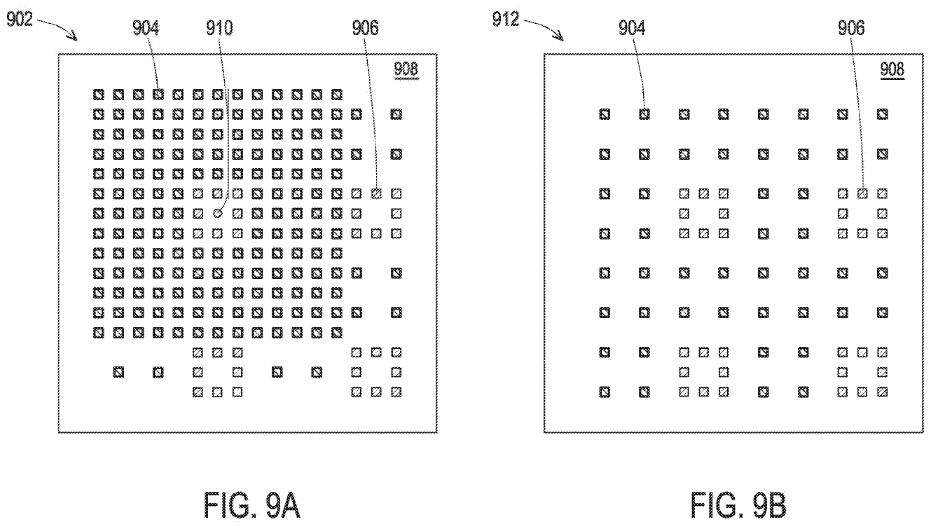

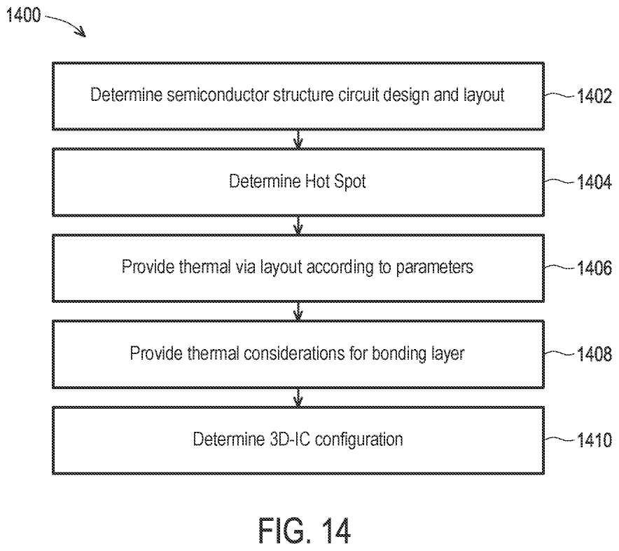

FIGS. 9A and 9B illustrate a top view of an IC chip or die that may be included in any one of the previously discussed embodiment including that of FIG. 1 or its embodiments of FIGS. 2A-8. The respective top views illustrate the distribution of thermal vias is non-uniform across a device region of the die. In some implementations, the thermal vias are positioned adjacent a determined hot spot of the die (e.g., localized). The localization may include the exclusion of thermal vias in other portions of a die, or the reduction in area covered by thermal vias in other portions of a die. The hot spot and thus the region for thermal vias may be determined by experimental results, simulation, design rules, design data, and/or other features including as discussed below with reference to FIG. 14.

FIG. 9A illustrates a top view of a first die or IC chip 902. The illustrated die 902 may be a portion of an IC chip including the circuit region, where different semiconductor features are formed such as the transistor features discussed above. In an embodiment, the die 902 is a logic chip. In an embodiment, the die 902 is a logic chip with a high-power device (e.g., high-power transistor). The high-power transistor may generate a hot spot 910. As such, the high-power transistor may be located at the location of the hot spot 910 (e.g., at a device-level below the via level shown).

Thermal vias 904 and electrical vias 906 are disposed on the first die 902. The thermal vias 904 may be substantially similar to the thermal vias 114 and 216 discussed above. The thermal vias 904 may be located above the device-level in BEOL features. In some implementations, the thermal vias 904 are copper. In an embodiment, the thermal vias 904 are isolated from the electrical vias 906 by dielectric 908, which may be substantially similar to IMD 218C discussed above. In an embodiment, the thermal vias 904 do not electrically connect to a semiconductor device of the die 902. The electrical vias 906 may be substantially similar to the electrical vias 218B discussed above. In some implementations, the electrical vias 906 include copper. In an embodiment, the electrical vias 906 are part of a multi-layer interconnect (MLI) and are coupled to metal lines. In an embodiment, the electrical vias 906 electrically connect (e.g., through the MLI) to a semiconductor device of the die 902. A plurality of electrical vias 906 are disposed adjacent the hot spot 910, e.g., adjacent a high-power semiconductor device. In some implementations, the adjacent electrical vias 906 are connected to the transistor terminals (e.g., source/drain or gate) of the high-power semiconductor device.

In an embodiment, the thermal vias 904 and the electrical vias 906 are substantially the same size and shape as illustrated in FIG. 9A. In other implementations, the thermal vias 904 and/or the electrical vias 906 are different shapes or sizes. In an embodiment, such as illustrated, the thermal vias 904 are substantially rectangular (e.g., square) in a top view. In an embodiment, such as illustrated, the electrical vias 906 are substantially rectangular (e.g., square) in a top view. However other configurations are possible including, but not limited to, those described in the following figures.

In an embodiment, the die 902 is comprised in a semiconductor structure including a stack of die (e.g., a 3D-IC). The die 902 may be configured substantially similar to one or more of die 104, 106, or 108 discussed above with reference to FIG. 1, and/or may be configured substantially similar to one or more of die 204, 206, or 208 discussed above with reference to FIGS. 2A-8.

FIG. 9B illustrates a top view of a second die or IC chip 912. The illustrated die 912 may be a portion of an IC chip including the circuit region, where different semiconductor features are formed such as the transistor features discussed above. In an embodiment, the die 912 is a logic chip having no high-power devices. In an embodiment, the die 912 is a memory chip.

Thermal vias 904 and electrical vias 906 are disposed on the second die 912. The thermal vias 904 may be substantially similar to the thermal vias 114 and/or 216 discussed above. In some implementations, the thermal vias 904 are copper. The thermal vias 904 may be located above the device-level in BEOL features. In an embodiment, the thermal vias 904 are isolated from the electrical vias 906 by dielectric 908, which may be substantially similar to IMD 218C discussed above. In an embodiment, the thermal vias 904 do not electrically connect to a semiconductor device of the die 912. The electrical vias 906 may be substantially similar to the electrical vias 218B discussed above. In some implementations, the electrical vias 906 include copper. In an embodiment, the electrical vias 906 are part of a multi-layer interconnect (MLI). In an embodiment, the electrical vias 906 electrically connect (e.g., through the MLI) to a semiconductor device of the die 912.

In an embodiment, the thermal vias 904 and the electrical vias 906 are substantially the same size and shape as illustrated in FIG. 9B. In some implementations, the thermal vias 904 and/or the electrical vias 906 are different shapes or sizes. In an embodiment, such as illustrated, the thermal vias 904 are substantially rectangular (e.g., square) in a top view. In an embodiment, such as illustrated, the electrical vias 906 are substantially rectangular (e.g., square) in a top view. In some implementations, the size of the thermal vias 904 and the electrical features 906 are substantially similar. The thermal vias 904 of the second die 912 are of a second quantity and have a second pitch between thermal vias 904.

In an embodiment, the quantity of thermal vias 904 of the second die 912 is less than the quantity of thermal vias 904 of the first die 902 (e.g., having a hot spot 910). In an embodiment, the pitch between thermal vias 904 in a region of the second die 912 is greater than the pitch between thermal vias 904 in a corresponding region of the first die 902 (e.g., having a hot spot 910). In an embodiment, the pitch between thermal vias 904 of the second die 912 is about twice the pitch between thermal vias 904 of the first die 902 (e.g., having a hot spot 910). In an embodiment, in another region of the first die 902 (not that localized around the hot spot 910) the quantity of thermal vias and/or pitch of the thermal vias is approximately equal to the corresponding region of the second die 912.

In an embodiment, the die 912 is comprised in a semiconductor structure (e.g., a 3D-IC) including a stack of die. The die 912 may be configured substantially similar to one or more of die 104, 106, or 108 discussed above with reference to FIG. 1. The die 912 may be configured substantially similar to one or more of die 302, 304, 402, or 404 discussed above with reference to FIGS. 2A-8. In an embodiment, a 3D-IC includes a stack of die including the first die 902 of FIG. 9A and the second die 912 of FIG. 9B. In a further embodiment, the second die 912 is a next adjacent die to the die 902 in a 3D-IC (e.g., above or below).

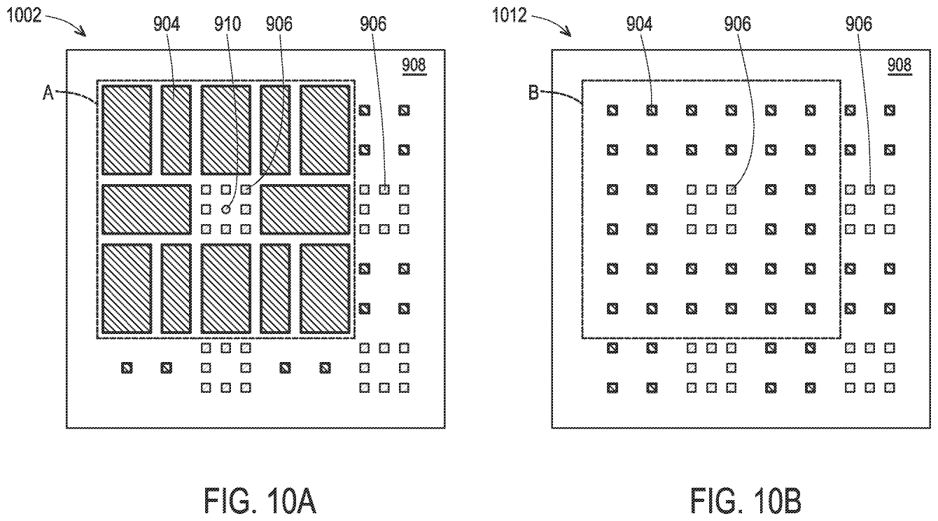

FIG. 10A illustrates a top view of a first die or IC chip 1002. The illustrated die 1002 may be a portion of an IC chip including the circuit region, where different semiconductor features are formed such as the transistor features discussed above. In an embodiment, the die 1002 is a logic chip. In an embodiment, the die 1002 is a logic chip with a high-power device (e.g., high-power transistor). The high-power transistor may generate a hot spot 910. As such, the high-power transistor may be located at the location of the hot spot 910 (e.g., at a device-level below the via level shown).

Thermal vias 904 and electrical vias 906 are disposed on the first die 1002. The thermal vias 904 may be substantially similar to the thermal vias 114 and 216 discussed above. In some implementations, the thermal vias 904 are copper. In an embodiment, the thermal vias 904 are isolated from the electrical vias 906 by dielectric 908, which may be substantially similar to IMD 218C discussed above. In an embodiment, the thermal vias 904 do not electrically connect to a semiconductor device of the die 902. The electrical vias 906 may be substantially similar to the electrical vias 218B discussed above. In some implementations, the electrical vias 906 include copper. In an embodiment, the electrical vias 906 are part of a multi-layer interconnect (MLI) and are coupled to metal lines. In an embodiment, the electrical vias 906 electrically connect (e.g., through the MLI) to a semiconductor device of the die 902. A plurality of electrical vias 906 are disposed adjacent the hot spot 910, e.g., adjacent a high-power semiconductor device. In some implementations, the adjacent electrical vias 906 are connected to the transistor terminals (e.g., source/drain or gate) of the high-power semiconductor device.

The thermal vias 904 and the electrical vias 906 may be different configurations (e.g., shapes) and sizes. In an embodiment, such as illustrated, the thermal vias 904 are substantially rectangular (e.g., rectangular extending in the y-direction or the x-direction) in a top view. In an embodiment, such as illustrated, the electrical vias 906 are substantially rectangular (e.g., square) in a top view. The thermal vias 904 may include larger vias and smaller vias. In some implementations, the smaller vias are substantially the same size and shape as the electrical vias 906. In some implementations, the larger thermal vias are 2 to 80 times larger than the electrical vias 906 of the die 1002.

In an embodiment, the die 1002 is comprised in a semiconductor structure (e.g., a 3D-IC) including a stack of die. The die 1002 may be configured substantially similar to one or more of die 104, 106, or 108 discussed above with reference to FIG. 1. The die 1002 may be configured substantially similar to one or more of die 204, 206, or 208 discussed above with reference to FIGS. 2A-8.

FIG. 10B illustrates a top view of a second die or IC chip 1012. The illustrated die 1012 may be a portion of an IC chip including the circuit region, where different semiconductor features are formed such as the transistor features discussed above. In an embodiment, the die 1012 is a logic chip having no high-power devices. In an embodiment, the die 1012 is a memory chip.

Thermal vias 904 and electrical vias 906 are disposed on the second die 1012. The thermal vias 904 may be substantially similar to the thermal vias 114 and/or 216 discussed above. In some implementations, the thermal vias 904 are copper. In an embodiment, the thermal vias 904 are isolated from the electrical vias 906 by isolation material 908, which may be substantially similar to IMD 218C discussed above. In an embodiment, the thermal vias 904 do not electrically connect to a semiconductor device of the die 912. The electrical vias 906 may be substantially similar to the electrical vias 218B discussed above. In some implementations, the electrical vias 906 include copper. In an embodiment, the electrical vias 906 are part of a multi-layer interconnect (MLI) and connected to metal lines of the MLI. In an embodiment, the electrical vias 906 electrically connect (e.g., through the MLI) to a semiconductor device of the die 912.

In some implementations, the thermal vias 904 and/or the electrical vias 906 are different shapes or sizes. In an embodiment, such as illustrated, the thermal vias 904 are substantially rectangular (e.g., square) in a top view. In an embodiment, such as illustrated, the electrical vias 906 are substantially rectangular (e.g., square) in a top view. In some implementations, the size of the thermal vias 904 and the electrical features 906 are substantially similar. In an embodiment, the area of thermal vias 904 of the second die 1012 is less than the area of thermal vias 904 of the first die 1002 (e.g., having a hot spot 910). In an embodiment, the area of thermal vias 904 of the second die 1012 is less than the area of thermal vias 904 of the first die 1002 when comparing an area surrounding the hot spot 910 of the first die 1002. For example, when stacked in a 3D-IC, a region A may be vertically aligned with a region B, where region A has a significantly greater area of thermal vias 904 than region B. In some implementations, other regions of the first die 1002 and the second die 1004 that are vertically aligned have substantially similar area of thermal vias 904.

In an embodiment, the die 1012 is comprised in a semiconductor structure (e.g., a 3D-IC) including a stack of die. The die 1012 may be configured substantially similar to one or more of die 104, 106, or 108 discussed above with reference to FIG. 1. The die 1012 may be configured substantially similar to one or more of die 302, 304, 402, or 404 discussed above with reference to FIGS. 2A-8. In an embodiment, a 3D-IC includes a stack of die including the first die 1002 of FIG. 10A and the second die 1012 of FIG. 10B. In a further embodiment, the second die 1012 is a next adjacent die to the die 1002 in a 3D-IC (e.g., above or below). As discussed above, the first die 1002 and the second die 1012 may be vertically aligned (e.g., region B is vertically aligned with region A).

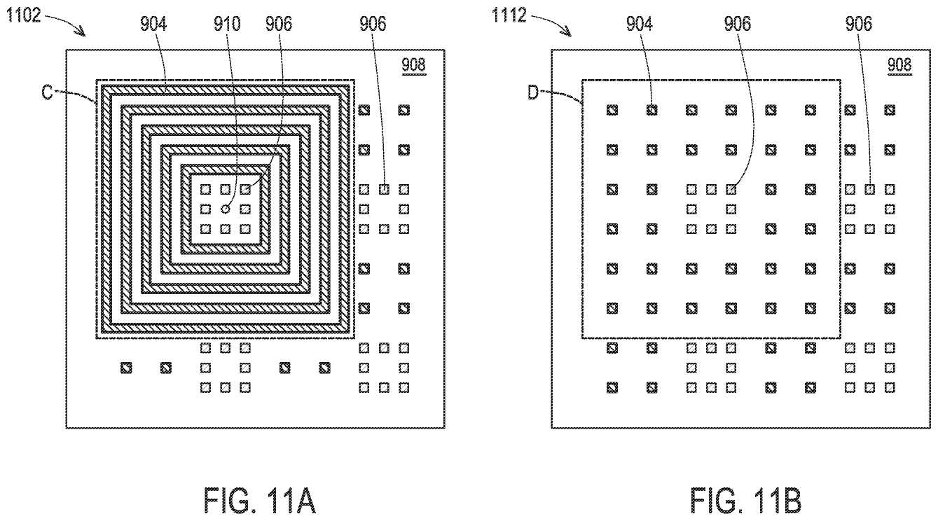

FIG. 11A illustrates a top view of a first die or IC chip 1102. The illustrated die 1102 may be a portion of an IC chip including the circuit region, where different semiconductor features are formed such as the transistor features discussed above. In an embodiment, the die 1102 is a logic chip. In an embodiment, the die 1102 is a logic chip with a high-power device (e.g., high-power transistor). The high-power transistor may generate a hot spot 910. As such, the high-power transistor may be located at the location of the hot spot 910 (e.g., at a device-level below the via level shown).

Thermal vias 904 and electrical vias 906 are disposed on the first die 1102. The thermal vias 904 may be substantially similar to the thermal vias 114 and/or 216 discussed above. In some implementations, the thermal vias 904 are copper. In an embodiment, the thermal vias 904 are isolated from the electrical vias 906 by dielectric 908, which may be substantially similar to IMD 218C discussed above. In an embodiment, the thermal vias 904 do not electrically connect to a semiconductor device of the die 902. The electrical vias 906 may be substantially similar to the electrical vias 218B discussed above. In some implementations, the electrical vias 906 include copper. In an embodiment, the electrical vias 906 are part of a multi-layer interconnect (MLI) and are coupled to metal lines. In an embodiment, the electrical vias 906 electrically connect (e.g., through the MLI) to a semiconductor device of the die 902. A plurality of electrical vias 906 are disposed adjacent the hot spot 910, e.g., adjacent a high-power semiconductor device. In some implementations, the adjacent electrical vias 906 are connected to the transistor terminals (e.g., source/drain or gate) of the high-power semiconductor device.

The thermal vias 904 and the electrical vias 906 are different configurations (e.g., shapes) and sizes as shown in FIG. 11A. In an embodiment, in a first region of the die 1102, the thermal vias 904 are substantially rectangular (e.g., square) in a top view. In an embodiment, such as illustrated, the electrical vias 906 are substantially rectangular (e.g., square) in a top view. In an embodiment, in another region of the die 1102, designated region C, thermal vias are elongated rings arranged in a concentric manner. The region C may be localized around the hot spot 910.

In an embodiment, the die 1102 is comprised in a semiconductor structure (e.g., a 3D-IC) including a stack of die. The die 1102 may be configured substantially similar to one or more of die 104, 106, or 108 discussed above with reference to FIG. 1. The die 1102 may be configured substantially similar to one or more of die 204, 206, or 208 discussed above with reference to FIGS. 2A-8.

FIG. 11B illustrates a top view of a second die or IC chip 1112. The illustrated die 1112 may be a portion of an IC chip including the circuit region, where different semiconductor features are formed such as the transistor features discussed above. In an embodiment, the die 1112 is a logic chip having no high-power devices. In an embodiment, the die 1112 is a memory chip.

Thermal vias 904 and electrical vias 906 are disposed on the second die 1112. The thermal vias 904 may be substantially similar to the thermal vias 114 and/or 216 discussed above. In some implementations, the thermal vias 904 are copper. In an embodiment, the thermal vias 904 are isolated from the electrical vias 906 by isolation 908. In an embodiment, the thermal vias 904 do not electrically connect to a semiconductor device of the die 1112. The electrical vias 906 may be substantially similar to the electrical vias 218B discussed above. In some implementations, the electrical vias 906 include copper. In an embodiment, the electrical vias 906 are part of a multi-layer interconnect (MLI) and are coupled to metal lines. In an embodiment, the electrical vias 906 electrically connect (e.g., through the MLI) to a semiconductor device of the die 1112.

In some implementations, the thermal vias 904 and/or the electrical vias 906 are similar shapes and/or sizes as illustrated in FIG. 11B. In an embodiment, the area of thermal vias 904 of the second die 1112 is less than the area of thermal vias 904 of the first die 1102 when comparing an area surrounding the hot spot 910 of the first die 1102. For example, when stacked in a 3D-IC, a region C may be vertically aligned with a region D, where region C has a significantly greater area of thermal vias 904 than region D. In some implementations, other regions of the first die 1002 and the second die 1004 that are vertically aligned have substantially similar area of thermal vias 904.

In an embodiment, the die 1112 is comprised in a semiconductor structure (e.g., a 3D-IC) including a stack of die. The die 1112 may be configured substantially similar to one or more of die 104, 106, or 108 discussed above with reference to FIG. 1. The die 1112 may be configured substantially similar to one or more of die 302, 304, 402, or 404 discussed above with reference to FIGS. 2A-8. In an embodiment, a 3D-IC includes a stack of die including the first die 1102 of FIG. 11A and the second die 1112 of FIG. 11B. In a further embodiment, the second die 1112 is a next adjacent die to the die 1102 in a 3D-IC (e.g., above or below). As discussed above, the first die 1102 and the second die 1112 may be vertically aligned (e.g., region D is vertically aligned with region C).

Note that the present disclosure contemplates any combinations of rectangular or square vias, rectangular bar-shaped vias, polygon-shaped vias, ring shaped vias, and other differently shaped vias. The thermal vias may elongate in a x-direction or a y-direction. In some implementations, the ring shaped vias may be continuous structures (e.g., as illustrated in FIG. 11A), in other implementations, the ring shaped vias may be non-continuous. The area of the thermal vias affects the thermal absorption (e.g., greater area provides greater thermal absorption) and thus, the shape and size may be determined based on the desired thermal performance.

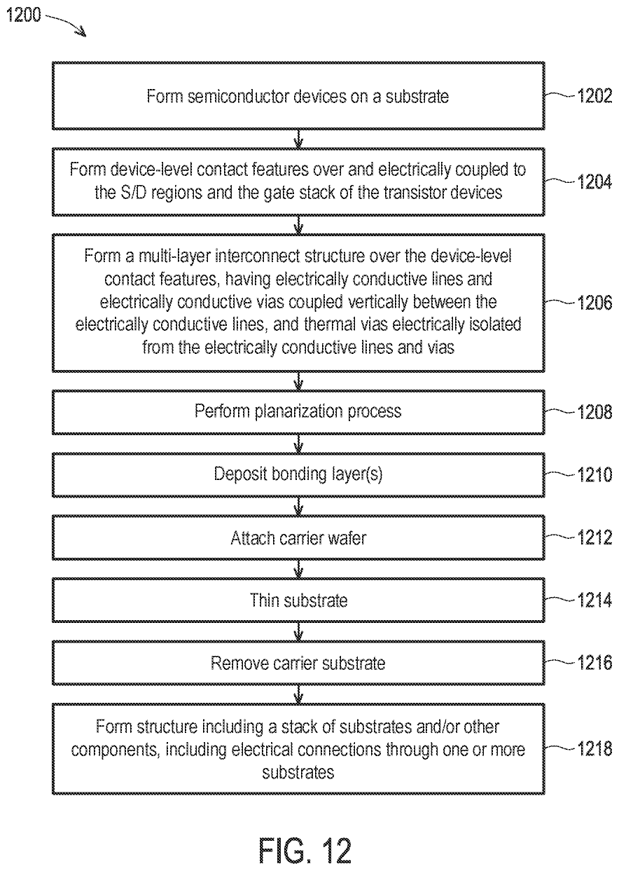

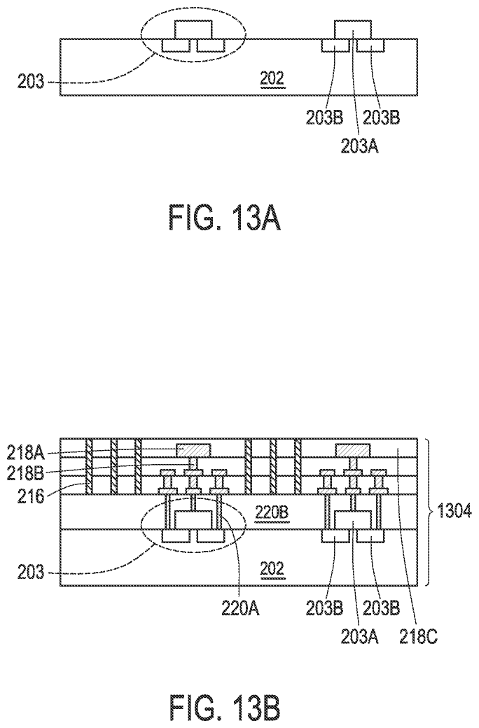

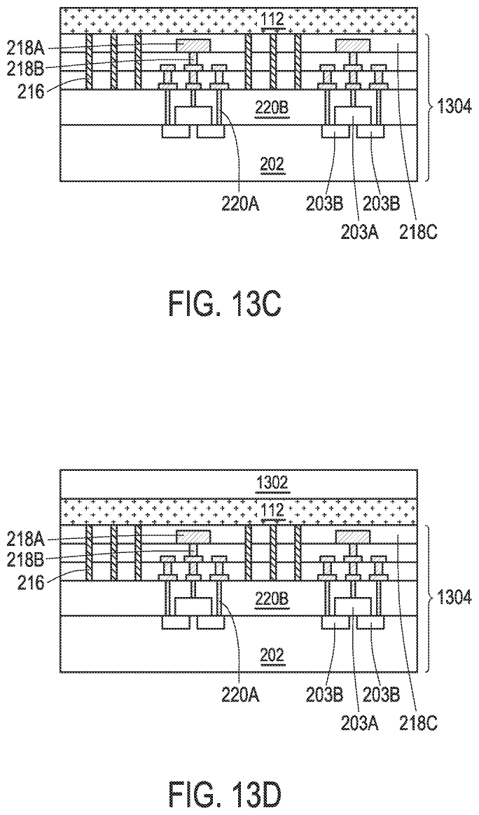

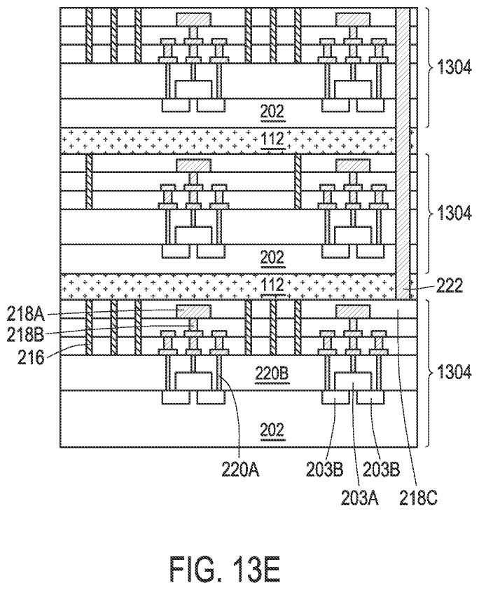

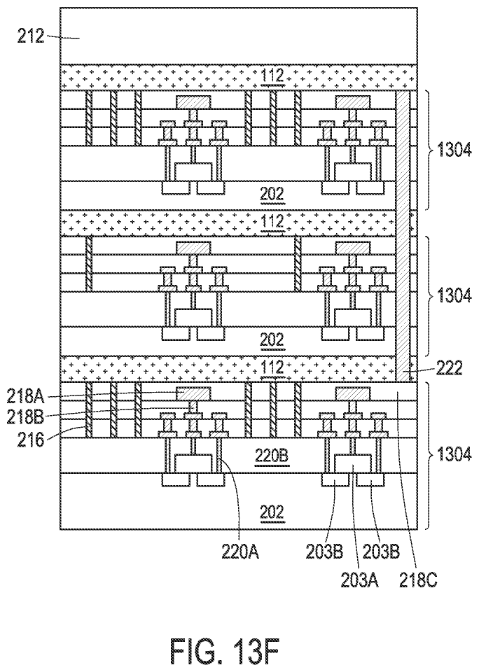

Referring now to FIG. 12, illustrated is a flow chart of a method 1200 to form an IC structure including a plurality of stacked die, according to one or more aspects of the present disclosure. The fabricated structure may be substantially similar to as discussed above including the embodiment of structure 100 of FIG. 1, or those embodiments illustrated in FIGS. 2A-8. FIGS. 13A, 13B, 13C, 13C, 13E, and 13F illustrate forming an IC structure 1300 at intermediate stages of fabrication, processed in accordance with the method 1200 of FIG. 12. FIGS. 13A-13F may illustrate features previously described, and some of these features will not be described again for the sake of brevity.

The method 1200 at block 1202 forms a plurality of semiconductor devices (e.g., transistor devices) on a substrate. Referring to the example of FIG. 13A, a plurality of semiconductor devices 203 are formed on a semiconductor substrate 202. The semiconductor devices 203 include a channel region between source/drain (S/D) regions 203B and a gate structure 203A over the channel region. The semiconductor devices 203 may be formed by any configuration (e.g., planar, GAA, FinFET) and be formed by suitable deposition and patterning techniques with suitable materials including as discussed above. In an embodiment, at least one of the semiconductor devices 203 is a high-power device.

The method 1200 at block 1204 forms device-level contact features over and electrically coupled to the semiconductor device. In an embodiment, the semiconductor device is a transistor and contact features are formed to the S/D regions and/or the gate structure of the device. Referring to the example of FIG. 13B, conductive contact features 220A extend through inter layer dielectric (ILD) 220B. The contact features 220A and ILD 220B, along with the semiconductor device 203, may be formed through suitable FEOL processing techniques. The FEOL processing may include depositing one or more ILD sublayers (e.g., CESL), performing one more patterning processes that include lithography and etching to form patterned openings in the ILD sublayers, performing one or more deposition processes such as CVD, PVD, or ALD to form metal features in the patterned trenches, and/or planarization processes such as CMP. In an embodiment, the contact features 220A include tungsten (W).

The method 1000 at block 1206 forms multi-layer interconnect (MLI) structure over the device-level contact features discussed in block 1204. A plurality of thermal vias are also formed in block 1206. Referring to the example of FIG. 13B, an MLI structure including metal lines 218A and metal vias 218B embedded in dielectric, IMD 218C are formed. The metal lines 218A and metal vias 218B are electrically coupled to the semiconductor devices 203. Thermal vias 216 are formed laterally spaced from electrical metal lines 218A and vias 218B and electrically isolated from the electrical metal lines 218A and vias 218B. The configuration of the thermal vias 216 including their quantity, shape, size, and location may be determined based on the desired thermal performance of the die. See FIG. 14 discussed below. In some implementations, an increased area of thermal vias are provided adjacent a hot spot of a die as compared to other regions of the die. In some implementations, an increased area or quantity of thermal vias is provided for one die as compared to another die (e.g., another die of the 3D-IC).

In some embodiments, the thermal vias 216 are formed after forming the metal lines 218A and electrical vias 218B. In some embodiments, the thermal vias 114 are formed by etching through multiple IMD layer 218C in a single etching process, thereby forming deep trenches, then depositing a metal (e.g., Cu) into the deep openings. In some embodiments, the thermal vias 216 are formed concurrently with the forming of the metal lines 218A and metal vias 218V. In this way, the thermal vias 216 are formed in multiple etching and depositing steps. As discussed above, the thermal vias 216 have an end interfacing the ILD 220B and are insulated from electrical connections to the semiconductor devices 203. The patterning of the thermal vias 216 may be defined according to the method 1400 of FIG. 14, discussed below. The thermal vias 216 may include etching openings, as discussed above, and depositing material by CVD, PVD, or other suitable deposition. Exemplary materials for the thermal via 216 includes copper (Cu), diamond nanoparticles, AlN, boron nitride nanoparticles, and/or other suitable materials.

The method 1200 proceeds to block 1208 where a planarization process is performed. The planarization process may be a chemical mechanical polish (CMP) or other suitable process. In an embodiment, the CMP process reduces the surface roughness to less than approximately 1 nanometer (e.g., peak-to-valley vertical distance). Referring to the example of FIG. 13B, the planarization process provides an upper surface comprising an IMD layer 218C and an end of the thermal vias 216. In some implementations, conductive portions of the MLI structure (e.g., metal line 218A or metal via 218B) are also included in the upper, planarized surface.

The method 1200 proceeds to block 1210 where bonding layer(s) are deposited. In some implementations, multiple bonding layers are deposited. In some implementations, a single bonding layer is deposited. The bonding layer(s) may be conformally deposited. Referring to the example of FIG. 13C, a thermal bonding layer 112 is formed. The thermal bonding layer 112 may be substantially similar to as discussed above including with reference to FIG. 1. In an embodiment, the bonding layer is AlN. The thickness and material(s) of the bonding layer(s) of block 1210 may be determined according to the method 1400 of FIG. 14 discussed below. The thermal bonding layer may be deposited by PVD, CVD, or other suitable deposition method. In some implementations, the deposition is provided below approximately 400° C.

In an embodiment, the method 1200 continues to block 1212 where a carrier substrate or wafer is attached. Referring to the example of FIG. 13D, a carrier substrate 1302 is attached. The carrier substrate 1302 may be in wafer-shape. The carrier substrate may include silicon (Si), or other semiconductor materials such as germanium (Ge), silicon carbide (SiC), silicon germanium (SiGe), diamond, and/or other suitable substrate. In some implementations of the method 1200, block 1214 thins the substrate from a surface (e.g., backside), while the carrier substrate is attached to the opposing surface. In block 1216, the carrier substrate maybe removed for further processing of the surface to which it is attached. In other implementations of the method 1200, one or more of blocks 1212, 1214, and 1216 are omitted. As illustrated in FIG. 13D, a first die 1304 having semiconductor devices 203, thermal vias 216, and a multi-layer interconnect having metal lines 218A and vias 218B providing electrical connection to the semiconductor devices 203 and being isolated from the thermal vias 216 is thus formed. The thermal bonding layer 112 is provided on an upper surface of the die 1304. In some implementations, a bonding layer may be deposited prior to the thermal bonding layer 112 such as illustrated in FIG. 2B.

The method 1200 includes block 1218 where a stack of substrates (e.g., die) or other components (e.g., heatsinks, etc.) are formed including the die fabricated in blocks 1202-1216. The additional die may be fabricated using one or more of blocks 1202-1216. Referring to the example of FIG. 13E, additional die 1304 are formed over the die 1304 and thermal bonding layer 112. Each die 1304 may have similar functionality or different functionality. In some implementations, the die 1304 are logic die (e.g., including low power and/or high-power devices) or memory die. The die 1304 are attached by bonding layers 112, which may be substantially similar to as discussed above.

In an embodiment, a through substrate via (TSV) 222 is formed through one or more die 1304 to connect the die 1304 to one another and/or to an input/output terminal of the structure. In some implementations, after attaching one or more die, an opening is etched extending through the die 1304 and filled with conductive materials to form the TSV 222. In some implementations, the TSV 222 is formed in multiple etching and deposition steps specific to a given die and then subsequently aligned when stacking the die 1304. FIG. 13F is illustrative of a thermal bonding layer 112 formed over an upper die 1304 and attaching a component 212. The component 212 may be a heat sink, carrier wafer, substrate, another die, package component, and/or other feature.

Referring now to FIG. 14, illustrated is a method 1400 of determining a thermal configuration of a 3D-IC. The thermal configuration may include a thermal via layout of an IC device and/or the thermal bonding layer parameters such as material(s) and thickness(es). In a block 1402 of the method 1400, a semiconductor structure circuit design and layout of one or more dies are determined. In an embodiment, one design determined is for a first IC die or chip such as a logic chip including one or more logic devices and their interconnections. In some implementations, the semiconductor circuit design and layout includes a high-power device such as a high-power transistor. In an embodiment, another design determined is for a second IC die or chip such as a logic chip or a memory chip that is to be stacked with the first chip for forming a 3D-IC structure. Block 1402 may include providing a layout suitable for a graphic database system (GDS) file or other layout data.

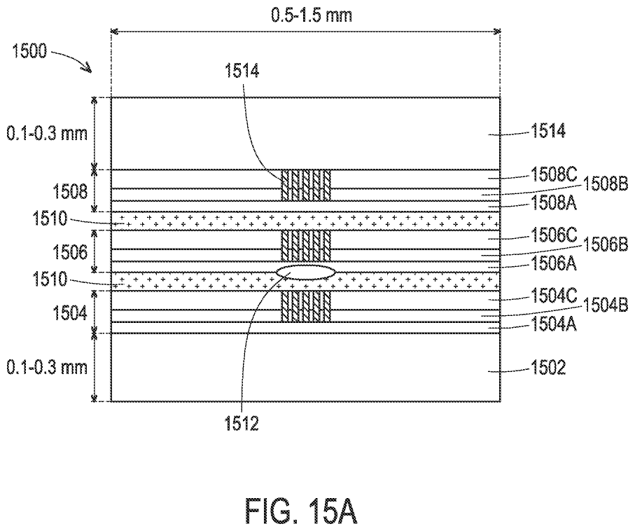

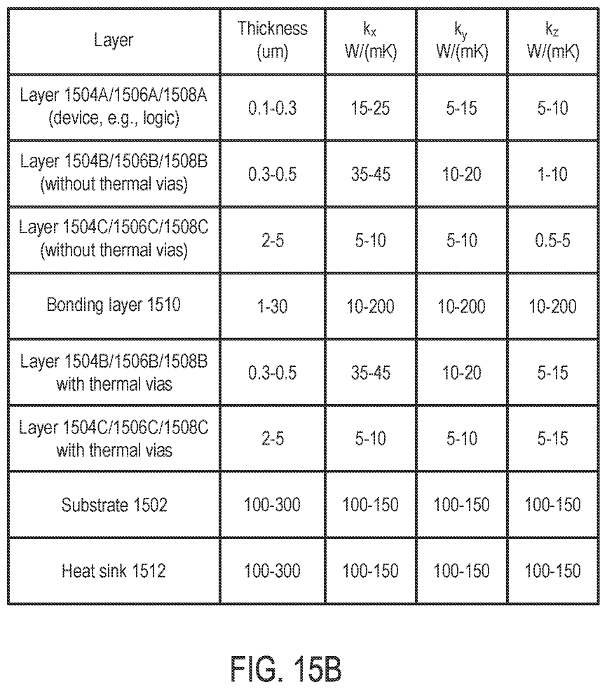

Referring to the example of FIG. 15A, illustrated is a 3D-IC structure 1500. The 3D-IC structure 1500 may be representative of a fabricated device, or may be representative of a model of die used in simulation techniques for the design of a 3D-IC. The structure 1500 includes a first die 1504 including a device-layer (e.g., substrate, semiconductor devices such as transistors) 1504A, a first interconnect layer 1504B, and a second interconnect layer 1504C, which may be first and second metal layers of an MLI, respectively. The structure 1500 includes a second die 1506 including a device-layer (e.g., substrate, semiconductor devices such as transistors) 1506A, a first interconnect layer 1506B and a second interconnect layer 1506C (e.g., first and second metal layers of an MLI). The structure 1500 includes third die 1508 including a device-layer (e.g., substrate, semiconductor devices such as transistors) 1508A, a first interconnect layer 1508B and a second interconnect layer 1508C (e.g., first and second metal layers of an MLI). A bonding layer 1510 interposes the first die 1504 and the second die 1506, interposes the second die 1506 and the third die 1508, and interposes the third die 1508 and a heat sink 1512. In an embodiment, one or more of the first die 1504, the second die 1506, or the third die 1508 have a thickness of approximately 4 microns (μm). The die stack is disposed on a substrate 1502 and a heat sink 1514 is disposed over the stack.

The method 1400 proceeds to block 1404 where a hot spot—an area of increased thermal energy as discussed above—is determined. The hot spot may be determined based on the design data of block 1402. In some implementations, the hot spot is determined by simulation of the design data of block 1402. In some implementations, the hot spots are identified from the design data by locating a high-power transistor.

Referring to the example of FIG. 15A, a hot spot 1512 is identified on the second, or middle, die 1506. In some implementations, the hot spot 1512 is identified by simulation. In some implementations, the hot spot 1512 is identified by evaluation of the design data to determine a high-speed transistor. In an embodiment, the hot spot 1512 is a 250 μm×250 μm hotspot in second die 1506 and in particular in the device layer 1504A (e.g., logic layer) of the second die 1506. In some implementations, the hot spot 1512 has a thermal energy of approximately 500 W/cm2.

In some implementations of block 1404 in addition to identifying a hot spot, the overall heating of the die of the 3D-IC structure is determined. In some implementations, the overall heating of the second die 1506 may be greater than the overall heating of the first die 1504 and the third die 1508. In some implementations, the overall heating of the second die 1506 may be an order of magnitude greater than the overall heating of the first die 1504 and the third die 1508. In an embodiment, the overall heating of the dies may be between approximately 0.05 W/cm2 and 2 W/cm2. In some embodiments, the overall heating of die 1506 may be less than the overall heating of die 1504 and/or die 1508.

In an embodiment, in determining a thermal performance of the 3D-IC and the die comprising the stack, a thickness (micron) and thermal resistance of each layer of each of die 1504, 1506, and 1508 are determined. Exemplary parameters are illustrated in FIG. 15B including in columns 3, 4, and 5, which illustrate the directional thermal coefficient of each of the elements of the structure 1500. In some implementations, the values in columns 3, 4, and 5 are utilized to simulate performance of the structure 1500.

The method 1400 proceeds to block 1406 where a thermal via layout is determined to address the heating of the structure and in particular identified hot spots of block 1404. In some implementations, the thermal via layout defines the quantity, size, and/or placement of thermal vias. The thermal via layout may be determined such that the thermal performance of the 3D-IC is sufficient (e.g., a maximum temperature is within design limits).

Referring to the example of FIG. 15A, thermal vias 1514 are illustrated. The thermal vias 1514 may be substantially similar to the thermal vias 114, 216, and/or 904 discussed above. Referring to the example of FIG. 15B, illustrated is a range of thicknesses and directional thermal resistance for layers of the die comprising thermal vias, which may be used to perform the simulations of the structure 1500 with respect to determining the inclusion of thermal vias. The determination may include the composition of the thermal vias (e.g., the thermal coefficient).

The method 1400 proceeds to block 1408 where the thermal considerations of a bonding layer associated with the die are determined. The thermal considerations may include simulation and/or experimental results to determine a composition and/or thickness of a thermal bonding layer of the die (e.g., in conjunction with overlying die or components such as heat sinks) that provides for sufficient thermal performance. In an embodiment, a thermal conductivity (k) of one or more thermal bonding layers is determined. In a further embodiment, a thickness of each of one or more thermal bonding layers is determined.

Referring to the example of FIG. 15A, bonding layer(s) 1510 are illustrated. The bonding layer 1510 may be substantially similar to the thermal bonding layer 112 and/or bonding layer 224 discussed above. In the example of FIG. 15B, illustrated is parameters for the bonding layer 1510 suitable for simulation and/or fabrication of the structure 1500 to determine suitable thermal performance for structure 1500.

In an embodiment, a heat transfer coefficient (HTC) boundary condition is set for the structure 1500 for the simulation methods including those discussed above. In an embodiment, a top HTC (HTCₜₒₚ) between approximately 150-200 W/m²/K and a distance of approximately 0.5 to 1.5 mm are provided. In an embodiment, a bottom HTC (HTC_{bottom}) between approximately 650-700 W/m²/K and a distance of approximately 0.5 to 1.5 mm are provided. In an embodiment, a side HTC (HTC_{side}) between approximately 150-200 W/m²/K is provided. In an embodiment, the substrate 1502 is approximately 0.1 to 0.3 mm in height. In an embodiment, the heat sink 1514 is approximately 0.1 to 0.3 mm in height.

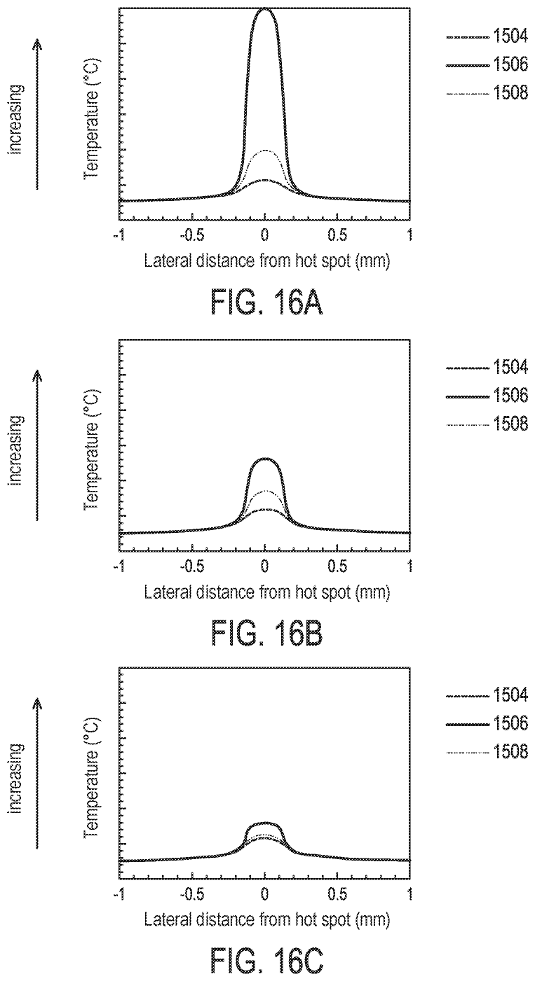

FIGS. 16A, 16B, and 16C illustrate graphical representations of portions of a structure designed, simulated, and/or fabricated according to the method 1400. FIGS. 16A, 16B, and 16C may be generated using simulation techniques implementing parameters as discussed above with reference to FIGS. 14, 15A, and 15B. FIG. 16A illustrates a temperature profile for a structure substantially similar to the structure 1500 having no thermal vias and a thermal bonding layer material having a thermal conductivity of approximately 1.4 W/m-K. FIG. 16B illustrates a temperature profile for a structure substantially similar to the structure 1500 having no thermal vias and a thermal bonding layer material having a thermal conductivity of approximately 10 W/m-K. FIG. 16A illustrates a temperature profile for a structure substantially similar to the structure 1500 having approximately 5% (by area) thermal vias with a thermal conductivity of the vias (kᵥᵢₐ) of approximately 150 W/m-K and a thermal bonding layer material having a thermal conductivity of approximately 30 W/m-K. As discussed above, the thermal vias may be comprised of copper, diamond, boron nitride, and/or other suitable materials and be positioned adjacent a hot spot of the structure (i.e., vertically aligned with the hot spot). The thermal vias may include a thermal conductivity (k)≥approximately 100 W/m/K. The maximum temperature is decreased from the simulation parameters of FIG. 16A to those of FIG. 16B. In an embodiment, the maximum temperature is decreased approximately 10 to 15% from the embodiment of FIG. 16A to that of FIG. 16B; and in an embodiment, the maximum temperature is decreased approximately 3 to 8 percent from the embodiment of FIG. 16B to the embodiment of FIG. 16C.

Although not limiting, the present disclosure offers advantages for IC semiconductor structures with distribution and dissipation of thermal energy. One example advantage is incorporating thermal vias on a die of a 3D-IC structure such that the thermal vias are surrounding a hot spot (e.g., a high-power device) of the die. The thermal vias may provide a vertical path for dissipation of the thermal energy. Another example advantage is incorporating a thermal bonding layer between die of the 3D-IC. The thermal bonding layer may provide a horizontal path for dissipation of the thermal energy.

One aspect of the present disclosure pertains to an integrated circuit (IC) structure including a first die and the a second die. The first die including a first transistor device formed on a substrate; a first multi-layer interconnect (MLI) over the substrate, wherein the first MLI includes a plurality of metal lines and interposing metal vias, and where the first MLI is electrically coupled to the first transistor device; and a first plurality of thermal vias laterally adjacent the first MLI. A thermal bonding layer is over the first die. The second die includes a second transistor device formed on another substrate; a second MLI over the another substrate, where the second MLI includes a plurality of metal lines and interposing metal vias and is electrically coupled to the second transistor device; and a second plurality of thermal vias laterally adjacent the second MLI. The second plurality of thermal vias is less than the first plurality of thermal vias.

In an embodiment, the first transistor device is a high-power transistor, and wherein the second transistor device is a logic transistor. In an embodiment, the thermal bonding layer is AlN. In a further implementation, the AlN extends from a dielectric layer of the first MLI of the first die to the another substrate of the second die. In another further implementation, the another bonding layer interposes the thermal bonding layer and the first die. The bonding layer may be at least one of Al2O3, SiO2, or SiN. In an embodiment, the first plurality of thermal vias laterally adjacent the first MLI is disposed in a first region of the first die and a third plurality of thermal vias is disposed in a second region of the first die. In a further embodiment, the first plurality of thermal vias has a greater area than the third plurality of thermal vias.

In an embodiment of the IC structure, the first plurality of thermal vias is disposed at a first pitch and the third plurality of thermal vias is disposed at a second pitch, the second pitch greater than the first pitch. In a further embodiment, the second plurality of thermal vias of the second die is disposed as the second pitch.

Another aspect of the present disclosure pertains to an integrated circuit (IC) structure. The IC structure includes a plurality of vertically stacked dies; a thermal bonding layer extending between a first die and a second die of the plurality of vertically stacked dies; and a plurality of thermal vias on at least one of the first die or the second die. The thermal bonding layer comprises a material having a thermal conductivity between approximately 10 and 500 W/m/K. The plurality of thermal vias are disposed adjacent a high-power transistor device.

In an embodiment, the material is AlN, diamond, boron nitride, Al₂O₃, BeO, or combinations thereof. In a further embodiment, the material extends from an uppermost dielectric layer of the first die to a surface of a substrate of the second die. In an implementation, the thermal bonding layer further includes another material of silicon nitride or silicon oxide. In an embodiment, the end of each of the plurality of thermal vias interfaces the thermal bonding layer. In an implementation, a total number of thermal vias of the first die is different than the total number of thermal vias of the second die. In a further example, the plurality of thermal vias is on a first region of the first die and a second plurality of thermal vias is on a second region of the first die, the first region having a greater density of thermal vias than the second region.

Another aspect of the present disclosure pertains a method of forming an integrated circuit (IC) structure. The method includes forming a first transistor device on a first die and a second transistor device on a second die. A first plurality of thermal vias is formed on the first die adjacent the first transistor device and a second plurality of thermal vias on the second die adjacent the second transistor device. The first plurality of thermal vias has a greater area than the second plurality of thermal vias. A thermal bonding layer is deposited on a surface of the first die. A second die is attached to the thermal bonding layer.

In an embodiment, depositing includes one of chemical vapor deposition (CVD) or physical vapor deposition (PVD). In a further embodiment, the forming the first plurality of thermal vias is performed after forming a multi-layer interconnect (MLI) on the first die. In an implementation, the method also includes providing design data of a circuit of the first die; identifying a hot spot on the first die; and positioning the first plurality of thermal vias adjacent the hot spot.

The details of the method and device of the present disclosure are described in the attached drawings. The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) structure, comprising:
a first die, the first die comprising:
a first transistor device formed on a substrate;
a first multi-layer interconnect (MLI) over the substrate, wherein the first MLI includes a plurality of metal lines and interposing metal vias, wherein the first MLI is electrically coupled to the first transistor device; and
a first plurality of thermal vias laterally adjacent the first MLI;
a thermal bonding layer over the first die; and
a second die over the thermal bonding layer, the second die comprising:
a second transistor device formed on another substrate;
a second MLI over the another substrate, wherein the second MLI includes a plurality of metal lines and interposing metal vias, wherein the second MLI is electrically coupled to the second transistor device; and
a second plurality of thermal vias laterally adjacent the second MLI, wherein the second plurality of thermal vias is less than the first plurality of thermal vias.

2. The IC structure of claim 1, wherein the first transistor device is a high-power transistor, and wherein the second transistor device is a logic transistor.

3. The IC structure of claim 1, wherein the thermal bonding layer is AlN.

4. The IC structure of claim 3, wherein the AlN extends from a dielectric layer of the first MLI of the first die to the another substrate of the second die.

5. The IC structure of claim 3, wherein another bonding layer interposes the thermal bonding layer and the first die.

6. The IC structure of claim 5, wherein the another bonding layer is at least one of Al2O3, SiO2, or SiN.

7. The IC structure of claim 1, wherein the first plurality of thermal vias laterally adjacent the first MLI is disposed in a first region of the first die and a third plurality of thermal vias is disposed in a second region of the first die.

8. The IC structure of claim 7, wherein the first plurality of thermal vias has a greater area than the third plurality of thermal vias.

9. The IC structure of claim 7, wherein the first plurality of thermal vias is disposed at a first pitch and the third plurality of thermal vias is disposed at a second pitch, the second pitch greater than the first pitch.

10. The IC structure of claim 9, wherein the second plurality of thermal vias of the second die is disposed as the second pitch.

11. An integrated circuit (IC) structure, comprising:
a plurality of vertically stacked dies;
a thermal bonding layer extending between a first die and a second die of the plurality of vertically stacked dies, wherein the thermal bonding layer comprises a material having a thermal conductivity between approximately 10 and 500 W/m/K; and
a plurality of thermal vias on at least one of the first die or the second die, wherein the plurality of thermal vias are disposed adjacent a high-power transistor device.

12. The IC structure of claim 11, wherein the material is AlN, diamond, boron nitride, Al₂O₃, BeO, or combinations thereof.

13. The IC structure of claim 12, wherein the thermal bonding layer further includes another material of silicon nitride or silicon oxide.

14. The IC structure of claim 11, wherein an end of each of the plurality of thermal vias interfaces the thermal bonding layer.

15. The IC structure of claim 11, wherein a total number of thermal vias of the first die is different than the total number of thermal vias of the second die.

16. The IC structure of claim 11, wherein the plurality of thermal vias is on a first region of the first die and a second plurality of thermal vias is on a second region of the first die, the first region having a greater density of thermal vias than the second region.

17. A method of forming an integrated circuit (IC) structure, comprising:
forming a first transistor device on a first die and a second transistor device on a second die;
forming a first plurality of thermal vias on the first die adjacent the first transistor device and a second plurality of thermal vias on the second die adjacent the second transistor device, wherein the first plurality of thermal vias has a greater area than the second plurality of thermal vias;
depositing a thermal bonding layer on a surface of the first die; and
attaching the second die to the thermal bonding layer.

18. The method of claim 17, wherein the depositing includes one of chemical vapor deposition (CVD) or physical vapor deposition (PVD).

19. The method of claim 18, wherein the forming the first plurality of thermal vias is performed after forming a multi-layer interconnect (MLI) on the first die.

20. The method of claim 17, further comprising:
providing design data of a circuit of the first die;
identifying a hot spot on the first die; and
positioning the first plurality of thermal vias adjacent the hot spot.
